(19) United States
(12) Patent Application Publication
(10) Pub. No.: US 2013/0267073 A1
(43) Pub. Date: Oct. 10, 2013

(54) Method of Manufacturing Fin Field Effect Transistor

(71) Applicants: Huaxiang Yin, Beijing (CN); Wei He, Beijing (CN); Huicai Zhong, San Jose, CA (US); Chao Zhao, Kessel-lo (BE); Dapeng Chen, Beijing (CN)

(72) Inventors: Huaxiang Yin, Beijing (CN); Wei He, Beijing (CN); Huicai Zhong, San Jose, CA (US); Chao Zhao, Kessel-lo (BE); Dapeng Chen, Beijing (CN)

(21) Appl. No.: 13/577,252

(22) PCT Filed: Jun. 7, 2012
(86) PCT No.: PCT/CN2012/000779

§ 371 Date: Aug. 5, 2012

(30) Foreign Application Priority Data
Apr. 8, 2012 (CN) 201210106806.X

(51) Int. Cl. H01L 21/336

(52) U.S. Cl. 438/283; 257/E21.421

(57) ABSTRACT

The present invention discloses a method of manufacturing a fin field effect transistor, which comprises the steps of forming a plurality of first fin structures on a substrate, which extend along a first direction parallel to the substrate; forming a plurality of second fin structures on a substrate, which extend along a second direction parallel to the substrate and the second direction intersecting with the first direction; selectively removing a part of the second fin structures to form a plurality of gate lines; and selectively removing a part of the first fin structures to form a plurality of substrate lines. In the method of manufacturing a fin field effect transistor according to the present invention, the gate lines and substrate lines are formed simultaneously by first making uniform silicon wing lines and gate wing lines using a limiting photolithography patternizing technique and then performing a centralized cutting of the corresponding specific regions, thereby increasing uniformity and reducing process difficulty and cost.

### CROSS REFERENCE

This application is a National Stage Application of, and claims priority to, PCT Application No. PCT/CN2012/000779, filed on Jun. 7, 2012, entitled “Method of Manufacturing Fin Field Effect Transistor”, which claims priority to Chinese Application No. 201210106806.X, filed on Apr. 8, 2012. Both the PCT application and the Chinese application are incorporated herein by reference in their entireties.

### FIELD OF THE INVENTION

The present invention relates to a method of manufacturing a fin field effect transistor, in particular to a method of manufacturing a fin field effect transistor where a silicon substrate and a gate fin structure are formed simultaneously.

### BACKGROUND OF THE INVENTION

Photolithography and the relevant Nano-Scale Lines Patterning are the key and base for the continuous scaling-down of the mainstream CMOS technique. As the critical line size has been scaled down to less than sub-32 nanometers, the conventional photolithography and patterning techniques are facing great challenges.

In the conventional projection exposing/photolithography system, the distinguishable minimum spacing (resolution) between two image points is δy=k1*λ/NA, wherein k1 is the scale factor, λ is the exposure wavelength, and NA is the numerical aperture. Therefore, the conventional methods for increasing the photolithography resolution substantially include: (1) reducing the exposure wavelength λ, i.e. changing DUV with a wavelength of 193 nanometers to EUV with a shorter wavelength; (2) increasing the numerical aperture NA, improving the light path, performing immersion exposure, etc.; (3) reducing the value of k1, using such techniques as Phase Shift Mask (PSM), Off Axis Illumination (OAI), Optical Proximate Correction (OPC).

However, since the lines are becoming thinner and thinner, line breaking and gathering phenomena usually occur in non-regular patterns, such as corner lines, thus the exposure for the critical dimension under 45 nanometers at present uses Double Patterning Lithography (DPL) in conjunction with a Design for Manufacturability (DFM), i.e. the circuit must be designed to be regular. Specifically, for example, a first photoresist is coated on a hard mask layer on a substrate and is then exposed and developed to form a first photoresist pattern having the same direction and length, and the hard mask layer is etched to transfer the pattern to the hard mask layer to form a first hard mask layer pattern. Since the direction and the length are the same, the limiting resolution can be increased. Then a second photoresist is coated and is exposed and developed to form a second photoresist pattern, with only a part of the first hard mask layer pattern exposed. The exposed first hard mask layer pattern is etched to remove the part that does not have to be connected and to form a second hard mask layer pattern. At last, the substrate or the structure in the underlayer is etched using the second hard mask layer pattern as a mask to form the final fine lines. Said technical uses less patterns which are usually in a negative form and do not have high requirements on the limiting resolution, so the DPL can expose lines of higher resolution.

On the other hand, in the Fin Field Effect Transistor (FinFET) with nanometer dimension, in addition to the gate, the silicon Fin has the critical dimension. DPL has to be performed to realize their respective nanometer patterns, namely, after forming the gate using the DPL technique, the DPL technique needs to be used again to form the silicon Fin, so the hard mask photolithography/etching needs to be performed at least twice, and accordingly, the photoresist exposing and developing need to be performed at least four times, thus resulting in a high process cost. Meanwhile, the non-uniform layout of the firstly formed silicon Fin pattern results in an increased complexity in the photolithography and patternizing of the gate using DPL, and extremely complicated situation may occur.

### SUMMARY OF THE INVENTION

In view of the above, the present invention aims at forming the silicon Fin and the Gate of the Fin FET simultaneously by gathering the cut lines of DPL at one time, thus increasing the uniformity and reducing process difficulty and cost.

To this end, the present invention provides a method of manufacturing a fin field effect transistor, which comprises the steps of: forming a plurality of first fin structures on a substrate, which extend along a first direction parallel to the substrate; forming a plurality of second fin structures on the substrate, which extend along a second direction parallel to the substrate, the second direction intersecting with the first direction; selectively removing a part of the second fin structures to form a plurality of gate lines; selectively removing a part of the first fin structures to form a plurality of substrate lines.

In the present invention, the step of forming a plurality of first fin structures on the substrate further comprises: providing the substrate and forming an active region; forming on the active region a plurality of photoresist patterns extending along the first direction; etching the active region using the photoresist patterns as a mask to form the plurality of first fin structures which are protruded and recessed portions between the first fin structures; and depositing oxide to fill the recessed portions so as to form shallow trench isolation.

In the present invention, the step of forming a plurality of second fin structures on the substrate further comprises: covering the entire substrate with a gate material and a hard mask; forming on the hard mask a plurality of photoresist patterns extending along the second direction; etching and removing the exposed hard mask by using the photoresist patterns as a mask, thereby exposing the gate material thereunder; etching the exposed gate material until exposing the first fin structures; and removing the photoresist patterns to obtain the second fin structures extending along the second direction.

In the present invention, the step of forming the gate lines further comprises: forming a photoresist on the entire substrate, exposing and developing the photoresist, to expose a plurality of rectangular window regions comprising a part of the second fin structures and a part of the first fin structures under the second fin structures; selectively etching to remove a part of the second fin structures and to leave the first fin structures in the exposed rectangular window regions; and removing the photoresist to leave the gate lines to be used as gates of the device.

In the present invention, the step of forming the substrate lines further comprises: forming a photoresist on the entire substrate, exposing and developing the photoresist, to expose a plurality of rectangular window regions comprising a part of the first fin structures; selectively etching to remove a part of the first fin structures; and removing the photoresist to leave the substrate lines to be used as source/drain regions and channel regions of the device.

In the present invention, the substrate lines comprise Si.

In the present invention, the gate lines comprise polysilicon, amorphous silicon or microcrystalline silicon.

In the present invention, the gate lines comprise metal, metal alloy or metal nitride.

In the present invention, after forming the substrate lines, comprising the steps of: selectively removing the gate lines to form gate trenches; filling the gate trenches with an interface material, a high-K gate insulating layer, a gate conductive layer of metal, metal alloy or metal nitride, and a gate filling layer of metal in sequence to form gate stack structures; depositing an interlayer dielectric layer on the entire substrate and planarizing said interlayer dielectric layer until exposing the gate stack structures; forming source/drain contact holes in the interlayer dielectric layer and filling said holes with metal to form source/drain contact plugs.

In the present invention, the plurality of first fin structures have the same length and width, the plurality of second fin structures have the same length and width, the plurality of gate lines have the same width but different lengths, and the plurality of substrate lines have the same width but different lengths.

In the method of manufacturing a fin field effect transistor according to the present invention, the gate lines and substrate lines are formed simultaneously by first making uniform silicon wing lines and gate wing lines using a limiting photolithography patternizing technique and then performing a centralized cutting of the corresponding specific regions, thereby increasing uniformity and reducing process difficulty and cost.

### BRIEF DESCRIPTION OF THE DRAWINGS

The technical solutions of the present invention will be described in detail below with reference to the drawings.

FIGS. 1-17 are top views of the steps of the method for manufacturing a fin field effect transistor according to the present invention; and

FIG. 18 is a schematic flow chart of the method for manufacturing a fin field effect transistor according to the present invention.

### DETAILED DESCRIPTION OF THE PREFERRED EMBODIMENTS

The features and technical effects of the technical solutions of the present invention will be described in detail below with reference to the drawings and in conjunction with the exemplary embodiments. A method of manufacturing a fin field effect transistor is disclosed, wherein the silicon Fin and the Gate of the Fin FET are formed simultaneously by gathering the cut lines of DPL at one time, thus increasing the uniformity and reducing process difficulty and cost. It shall be pointed out that like reference signs denote like structures, the terms “first”, “second”, “on”, “under” etc. appeared in this application can define various device structures or manufacturing procedures. Such definitions do not suggest the spatial, sequential or hierarchical relation of the defined device structures or manufacturing procedures unless otherwise indicated.

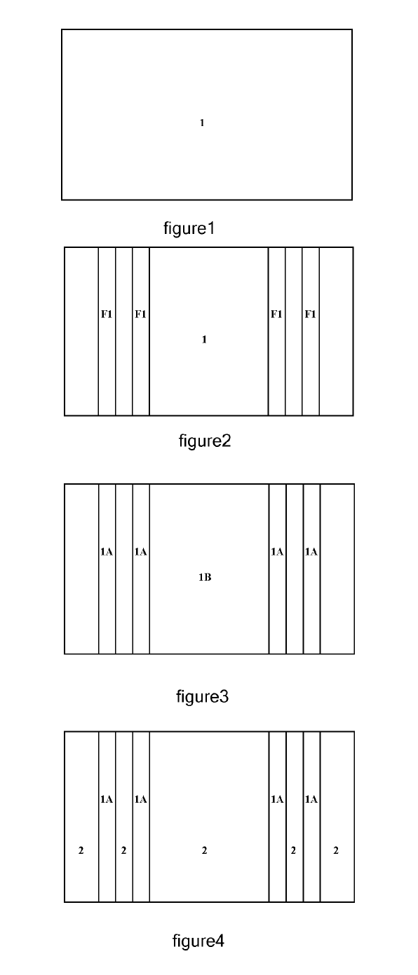

The steps of the method for manufacturing a fin field effect transistor according to the present invention will be described in detail below in conjunction with the flow chart of FIG. 18 and with reference to the top views in FIGS. 1-17.

Referring to FIG. 18 and FIGS. 1-4, a plurality of first fin structures are formed on a substrate, which extend along a first direction parallel to the substrate.

Referring to FIG. 1, a substrate is provided and an active region 1 is formed. The substrate is reasonably selected according to the need of the use of the device, and it may include monocrystalline silicon (Si), Silicon On Insulator (SOI), monocrystalline germanium (Ge), Germanium On Insulator (GeOI), strained silicon (Strained Si), germanium-silicon (SiGe) or a compound semiconductor material like gallium nitride (GaN), gallium arsenide (GaAs), indium phosphide (InP) or indium antimonide (InSb), or carbon-based semiconductor such as graphene, SiC or carbon nanotube. Preferably, the substrate is bulk silicon or SOI. The region of the substrate where the device is to be formed is the active region 1.

Referring to FIG. 2, a plurality of definition lines F1 is formed on the active region 1, which extend along a first direction parallel to the substrate surface. Wherein, F1 is, for example, a spin-coated photoresist, which has a first width W1 and is used for defining Si fin structures that will be used as source/drain regions and channel region, i.e. silicon wing (fin) lines.

Referring to FIG. 3, the active region 1 of the substrate is etched using F1 as a mask to form protruded fin structure portions 1A, and the remaining portions 1B of the active region of the substrate are recessed. 1A also has a width W1.

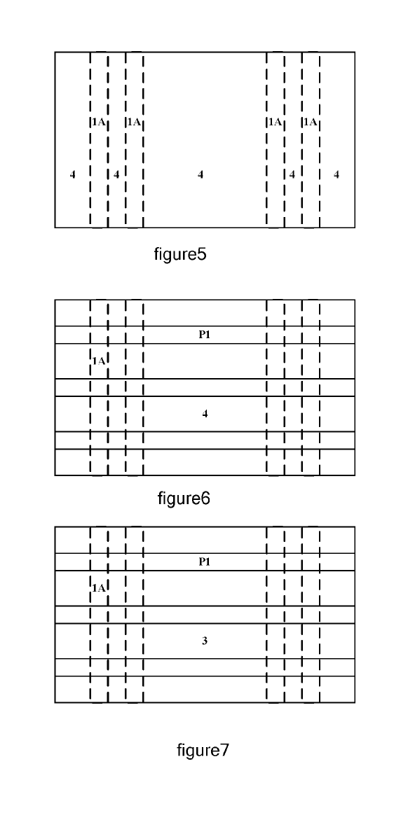

Referring to FIG. 4, an oxide, such as silicon oxide, is deposited to fill the recessed portions 1B, thus forming shallow trench isolations (STI) 2. FIGS. 3 and 4 show that the plurality of fin structures 1A formed by the material of the active region 1 of the substrate extend along a first direction parallel to the substrate surface and they have the same length, the same width but different distance in spacing. Wherein the surface of the STI2 is higher than the surface of the recessed portions 1B but lower than the surface of the protruded fin structures 1A.

Referring to FIG. 18 and FIGS. 5-9, a second fin structure is formed on the substrate, which extends along a second direction parallel to the substrate, wherein the second direction intersects with, preferably perpendicular to, the first direction.

Referring to FIG. 5, the entire substrate is covered with a gate material 3 and a hard mask 4. Wherein the rectangle shown by dashed lines represents the fin structure 1A buried under the gate material 3 and the hard mask 4. Likewise, all the dashed lines represent the understructures buried under the superstructures, hereafter. The recessed portion between 1A is STI2. When a gate-first process is used, the gate material 3 is doped polysilicon, metal, metal alloy, or metal nitride and combinations thereof. When a gate-last process is used, the gate material 3 is polysilicon, amorphous silicon or microcrystalline silicon. The material of the hard mask 4 is, for example, silicon oxide, silicon nitride and a combination thereof. Preferably, there is a pad oxide layer (not shown) under the gate material 3 so as to protect the substrate surface in the gate last process, or there is a gate insulating layer (not shown) in the gate first process. The gate insulating layer may include silicon oxide or high-K material.

Referring to FIG. 6, a plurality of definition lines P1 is formed on the hard mask 4, which extend along a second direction parallel to the substrate surface. P1 are, for example, photoresist patterns obtained by spin-coating and then exposing and developing, which have a second width W2 and are used for defining the fin structures that will be used as the gates, i.e. the gate lines.

Referring to FIG. 7, the exposed hard mask 4 is etched and removed by using P1 as a mask, thus exposing the gate material 3 thereunder.

Referring to FIG. 8, the exposed gate material 3 is etched until exposing the first fin structures 1A and STI2.

Referring to FIG. 9, P1 are removed to obtain second fin structures 3A on the substrate, which extend along a second direction parallel to the substrate, wherein the second direction intersects with, preferably perpendicular to, the first direction. FIGS. 8 and 9 show that the plurality of second fin structures 3A formed by the gate material 3 extend along a second direction parallel to the substrate surface, and they have the same length, the same width W2 but different distance in spacing. The second fin structures 3A cross over the first fin structures 1A. Preferably, spacer structures (not shown) made of silicon oxide or silicon nitride are formed on both sides of each of the second fin structures 3A.

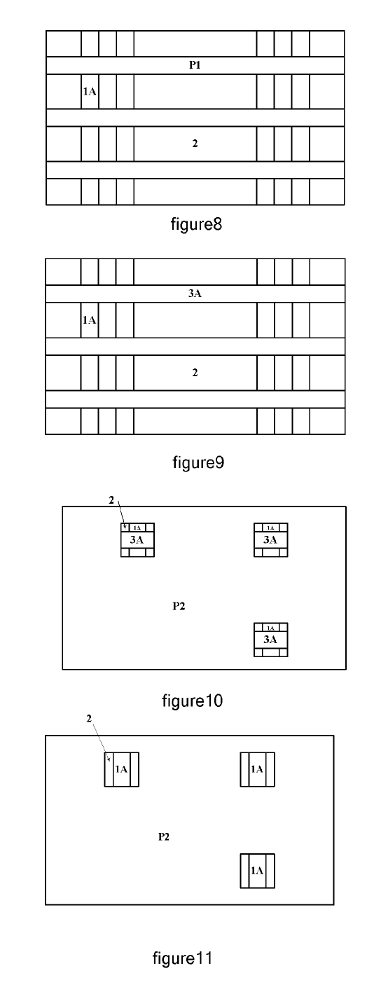

Referring to FIG. 18 and FIGS. 10-12, a part of the second fin structures is removed to form gate lines.

Referring to FIG. 10, photoresist P2 is formed on the entire active region and is exposed and developed, and the exposed plurality of rectangular window regions comprise a part of the second fin structures 3A, a part of the first fin structures 1A under 3A, and a part of STI2.

Referring to FIG. 11, a part of the second fin structures 3A formed by the gate material 3 is removed by selectively etching, leaving only the first fin structures 1A and STI2 in the exposed rectangular window region. With respect to the second fin structures 3A made of polysilicon, amorphous silicon or microcrystalline silicon, they have the similar property to the silicon material of substrate 1 and hence are dry removed through plasma etching. The end point for etching is controlled by controlling the process condition and etching time. With respect to the second fin structures 3A made of metal or insulator, they can be removed by wet etching liquid, preferably, by those solutions having a high etching selectivity, so that the STI2 made of silicon oxide and the first fin structures 1A made of silicon are substantially not etched or are etched at a low rate.

Referring to FIG. 12, the photoresist is removed to leave the gate lines used as the MOSFET gates (floating gate, control gate, erase gate, etc.) Wherein the gate lines are formed by the second fin structures 3A, which include a plurality of parallel lines extending along a second direction, and the lines have different lengths but the same width W2, and the line spacings are set according to the design of layout.

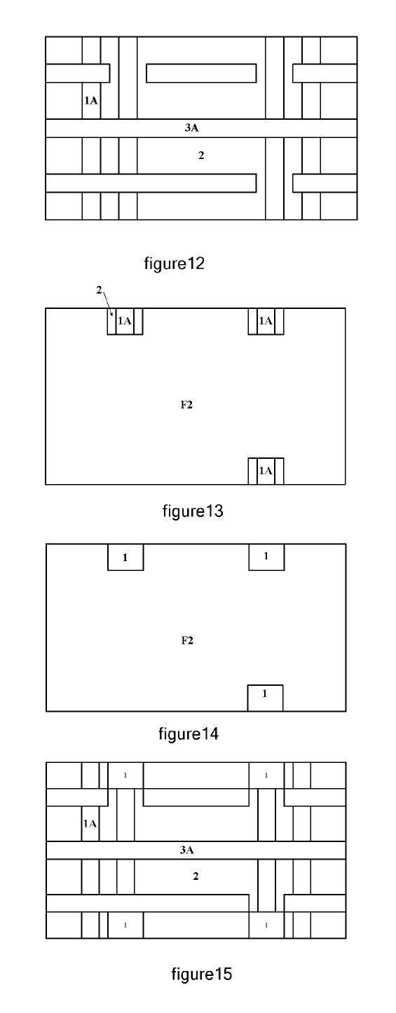

Referring to FIG. 18 and FIGS. 13-16, a part of the first fin structures are selectively removed to form substrate lines.

Referring to FIG. 13, photoresist F2 is formed on the entire active region and is exposed and developed, and the exposed plurality of rectangular window regions include a part of the first fin structures 1A and a part of STI2.

Referring to FIG. 14, a part of the first fin structures 1A made of the substrate material and a part of STI2 are removed by selective etching, leaving only the bottom Si substrate 1 in the exposed rectangular window region. The surface of the bottom Si substrate 1 left is lower than the surfaces of the surrounding fin structures 1A, the STI2, and the photoresist, and is parallel to the surfaces of the original recessed portions 1B, so Si trenches are formed. Similarly, dry etching or wet etching may be used. The first fin structures 1A are cut off in said rectangular window, thus controlling the shape and size of the source/drain regions of the device.

Referring to FIG. 15, the photoresist is removed to leave the substrate lines to be used as the source/drain regions and channel regions of the device. Wherein, the substrate lines are formed by the first fin structures 1A, which include a plurality of parallel lines extending along a first direction. The lines have different lengths but the same width W1, and the line spacings are set according to the need of the layout. Preferably, in the area where the substrate lines intersect with the gate lines, source/drain regions are formed in the substrate lines on both sides of the gate lines, and the overlapping portions of the substrate lines under the gate lines form the channel regions.

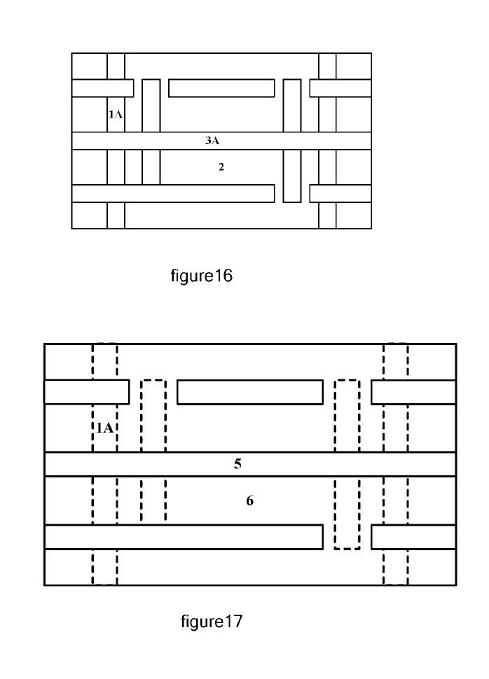

Referring to FIG. 16, the trenched in FIG. 14 are filled with silicon oxide, so that the surfaces of the STI2 in the entire active region are flush.

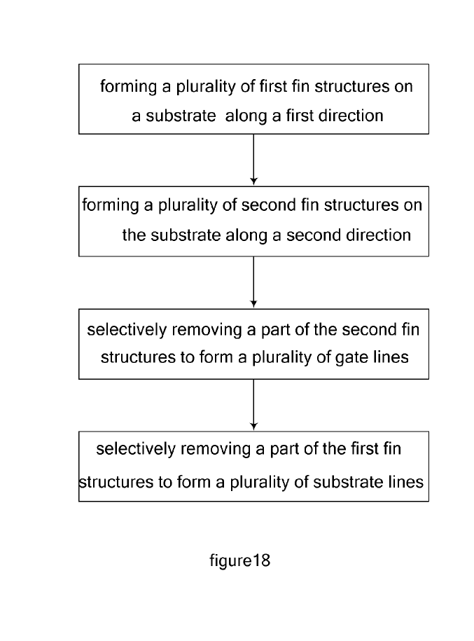

Finally, referring to FIG. 17, the subsequent process is completed. For example, in the gate last process, the gate lines are selectively removed to form gate trenches, and the gate trenches are filled with an interface material, a high-K gate insulating layer, a gate conductive layer of metal, metal alloy or metal nitride, and a gate filling layer of metal in sequence to form gate stack structures 5. Then an interlayer dielectric layer 6 is deposited on the entire active region and is planarized by CMP until exposing the gate stack structures. Wherein, the high-K material includes, but is not limited to, a hafnium-based material selected from a group consisting of HfO₂, HfSiOₓ, HfSiON, HfAlOₓ, HfTaOₓ, HfLaOₓ, HfAlSiOₓ and HfLaSiOₓ (wherein the content x of oxygen atom in each of the materials can be adjusted appropriately according to the different proportions of multiple metal components and the chemical valences thereof and x could be for example 1-6 and is not limited to an integer), or includes a rare earth based high-K dielectric material selected from a group consisting of ZrO₂, La₂O₃, LaAlO₃, TiO₂ and Y₂O₃, or includes Al₂O₃, and a composite layer of the above-mentioned materials. The gate conductive layer can be polysilicon, polycrystalline germanium-silicon or metal, wherein the metal may include such metal substance as Co, Ni, Cu, Al, Pd, Pt, Ru, Re, Mo, Ta, Ti, Hf, Zr, W, Ir, Eu, Nd, Er and La, or alloys of said metals and nitrides of said metals, and such elements as C, F, N, O, B, P and As can be doped to adjust the work function. A nitride barrier layer (not shown) is preferably formed between the gate conductive layer and the gate insulating layer through conventional methods like PVD, CVD and ALD, and the material of the barrier layer is MₓN_{y}, MₓSi_{y}N_{z}, MₓAl_{y}N_{z} or MₐAlₓSi_{y}N_{z}, wherein, M is Ta, Ti, Hf, Zr, Mo, W or other elements. Preferably, a source/drain contact hole may also be formed in the interlayer dielectric layer 6 and be filled with metal to form a source/drain contact plug (not shown).

In the method of manufacturing a fin field effect transistor according to the present invention, the gate lines and substrate lines are formed simultaneously by first making uniform silicon wing lines and gate wing lines using a limiting photolithography and patternizing technique and then performing a centralized cutting of the corresponding specific regions, thereby increasing uniformity and reducing process difficulty and cost.

Although the invention has been described in conjunction with one or more exemplary embodiments, those skilled in the art can understand that various appropriate changes and equivalents can be made to the device structure without departing from the scope of the invention. In addition, many modifications that might be adapted to specific situations or materials can be made from the disclosed teaching without departing from the scope of the invention. Therefore, the present invention is not intended to define the specific embodiments disclosed as the preferred ways of implementing the invention, but the disclosed device structure and the manufacturing method thereof will include all embodiments that fall into the scope of the present invention.

What is claimed is:

1. A method of manufacturing a fin field effect transistor, which comprises the steps of
forming a plurality of first fin structures on a substrate, which extend along a first direction parallel to the substrate;
forming a plurality of second fin structures on the substrate, which extend along a second direction parallel to the substrate, the second direction intersecting with the first direction;
removing a part of the second fin structures selectively, to form a plurality of gate lines; and
removing a part of the first fin structures selectively, to form a plurality of substrate lines.

2. The method of manufacturing a fin field effect transistor according to claim 1, wherein the step of forming a plurality of first fin structures on the substrate comprises:
providing the substrate and forming an active region;
forming on the active region a plurality of photoresist patterns extending along the first direction;
etching the active region using the photoresist patterns as a mask to form the plurality of first fin structures which are protruded and recessed portions between the first fin structures; and
depositing oxide to fill the recessed portions so as to form shallow trench isolation.

3. The method of manufacturing a fin field effect transistor according to claim 1, wherein the step of forming a plurality of second fin structures on the substrate comprises:
covering the entire substrate with a gate material and a hard mask;
forming on the hard mask a plurality of photoresist patterns extending along the second direction;
etching and removing the exposed hard mask by using the photoresist patterns as a mask, thereby exposing the gate material thereunder;
etching the exposed gate material until exposing the first fin structures; and
removing the photoresist patterns to obtain the second fin structures extending along the second direction.

4. The method of manufacturing a fin field effect transistor according to claim 1, wherein the step of forming the gate lines comprises:
forming a photoresist on the entire substrate, exposing and developing the photoresist, to expose a plurality of rectangular window regions comprising a part of the second fin structures and a part of the first fin structures under the second fin structures;
etching selectively to remove a part of the second fin structures and to leave the first fin structures in the exposed rectangular window regions; and
removing the photoresist to leave the gate lines to be used as gates of the device.

5. The method of manufacturing a fin field effect transistor according to claim 1, wherein the step of forming the substrate lines comprises:
forming a photoresist on the entire substrate, exposing and developing the photoresist, to expose a plurality of rectangular window regions comprising a part of the first fin structures;
etching selectively to remove a part of the first fin structures; and
removing the photoresist to leave the substrate lines to be used as source/drain regions and channel regions of the device.

6. The method of manufacturing a fin field effect transistor according to claim 1, wherein the substrate lines comprise Si.

7. The method of manufacturing a fin field effect transistor according to claim 1, wherein the gate lines comprise polysilicon, amorphous silicon or microcrystalline silicon.

8. The method of manufacturing a fin field effect transistor according to claim 1, wherein the gate lines comprise metal, metal alloy or metal nitride.

9. The method of manufacturing a fin field effect transistor according to claim 1, after forming the substrate lines, further comprising the steps of:
removing selectively the gate lines to form gate trenches;
filling the gate trenches with an interface material, a high-K gate insulating layer, a gate conductive layer of metal, metal alloy or metal nitride, and a gate filling layer of metal in sequence to form gate stack structures;
depositing an interlayer dielectric layer on the entire substrate and planarizing said interlayer dielectric layer until exposing the gate stack structures; and
forming source/drain contact holes in the interlayer dielectric layer and filling said holes with metal to form source/drain contact plugs.

10. The method of manufacturing a fin field effect transistor according to claim 1, wherein the plurality of first fin structures have the same length and width, the plurality of second fin structures have the same length and width, the plurality of gate lines have the same width but different lengths, and the plurality of substrate lines have the same width but different lengths.
